(19) United States
(12) Patent Application Publication
(10) Pub. No.: US 2009/0217975 A1
(43) Pub. Date: Sep. 3, 2009

(54) Glassless Solar Power Module Comprising at Least One Flexible Thin-Film Solar Cell and Method for Producing the Same

(75) Inventors: Klaus Kalberlah, Berlin (DE); Klaus Schlemper, Berlin (DE)

Correspondence Address: NORRIS, MCLAUGHLIN & MARCUS, P.A., 875 THIRD AVE, 18TH FLOOR, NEW YORK, NY, 10022, US

(73) Assignee: PVFLEX SOLAR GMBH, FÜRSTENWALDE (DE)

(21) Appl. No.: 12/295,659

(22) PCT Filed: Mar. 30, 2007
(86) PCT No.: PCT/EP2007/053094

§ 371 Date: Dec. 17, 2008

(30) Foreign Application Priority Data
Apr. 1, 2006 (DE) 10 2006 016 280.3

(51) Int. Cl. H01L 31/00; B05D 5/12; C23C 14/34

(52) U.S. Cl. 136/256; 427/74; 204/192.15

(57) ABSTRACT

The invention relates to thin-film solar power modules. The problem associated with known thin-film solar power modules is that the barrier effect of the front film does not prevent moisture from permeating the space between the solar cell and the cover film when exposed to moisture over a longer period of time. In order to solve this problem, the solar module comprises, starting from the solar cell (6), the following layer structure: front: an inorganic barrier layer (2), an inorganic-organic hybrid polymer barrier layer (3), a transparent adhesive layer (4a), a transparent cover film (1b); back: a transparent adhesive layer (4b), a standard backing film (7b).

The invention relates to a glassless solar power module with at least one flexible thin-film solar cell and a process for its manufacture.

Solar power modules are normally manufactured by encapsulating crystalline solar cells between a silicate glass pane facing the light and a second, rear silicate glass pane or a rear plastic foil and by covering the solar cells on the front side and the rear side with a hot-melt adhesive foil made of EVA (ethylene vinyl acetate). The entire “packet” is then immovably glued together in a so-called “laminator” by applying a slight pressure, a slight vacuum and heat so as to prevent to the greatest possible extent moisture and oxygen from the ambient air from entering the solar cells. In this way, aging and/or power loss of the solar cells should be kept as small as possible during the useful life of the solar module of 20-30 years. Obviously, silicate glass panes represent an effective barrier by keeping out moisture and oxygen from the air even under extreme climate conditions, but they have the disadvantage of not being flexible/bendable.

Solar modules operating on the basis on one of the so-called thin-film technologies are typically more susceptive to effects from the ambient atmosphere on the photoactive layer than solar modules having crystalline silicon cells. On the other hand, these thin-film techniques provide the opportunity to manufacture flexible modules, because the photovoltaic thin films, unlike crystalline cell wafers, are flexible. However, the cover pane made of silicate glass and facing the light must then be replaced with a flexible, highly transparent plastic foil.

Such solar modules are commercially available in limited quantity. A dense special foil must be used as front cover, because this foil should be impervious to water vapor equivalent to a silicate glass pane. Typically, foils made of ETFE or PTFE {ethylene tetrafluoroethylene copolymer, polytetrafluoroethylene} are used, whose blocking effect is enhanced by undercoating with silicon oxide (SiOₓ). These special foils are relatively expensive not only because of the silicon oxide coating deposited by evaporation, but more generally because of the employed materials.

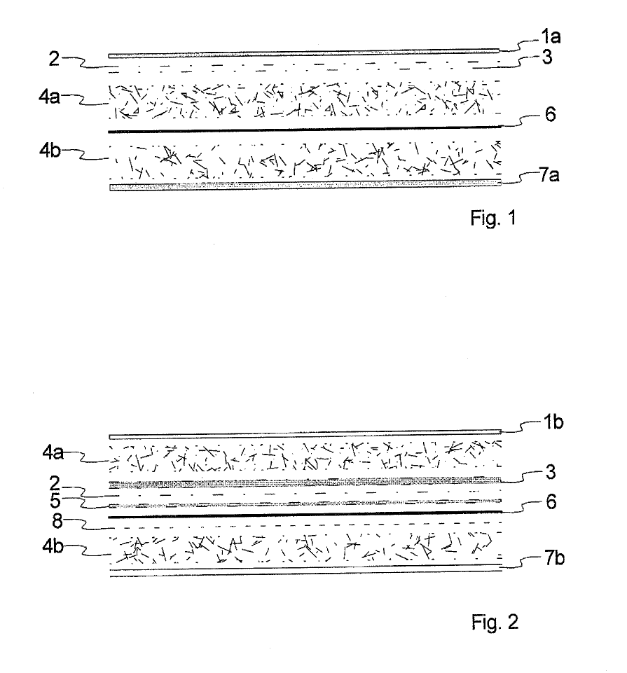

FIG. 1 shows typical encapsulation of solar cells between foils: preferably, the aforementioned fluoropolymers are used for the front foil 1a, which is almost completely impervious to diffusion, while the manufacturer of the special solar foil evaporates an inorganic barrier layer 2, typically made of silicon oxide, on the bottom side.

It has been suggested to provide the front foil with an additional, silicate-containing organic-inorganic hybrid polymer barrier layer 3 (known, for example, under the brand name ORMOCER). The hybrid polymer can be produced by a sol gel process.

The Fraunhofer ISC Annual Report 2004, pages 22 to 25, describes in the article Flexible Polymer Barrier Films for Encapsulation of Solar Cells the HIPRPLOCO supported project of the EU and the encapsulation of cells by using a closed system, i.e., by enhancing the blocking effect of foils using ORCOCER.

The manufacture of inorganic-organic hybrid polymers and their use as a barrier layer are known from DE 196 50 286 A1 (“Verpackungsmaterial”, Packaging Material). For example, DE 196 15 192 A1 discloses their use as aroma barrier or fragrant barrier layer.

However, this new development is not yet ready for market introduction. For reasons that will be described below, such approach is also not quite suitable for effectively protecting a solar cell against the harmful effect caused by moisture.

The manufacturer of the solar modules applies the high-density composite foil (1a, 2, 3) onto a solar cell 6 with a hot-melt adhesive 4a. The conventional layer structure on the backside of the solar cell 6 consists of an additional layer of hot-melt adhesive 4b and a composite foil 7a, which in turn is constructed from two plastic foils and an intermediate thin aluminum foil. The manufacturer of the modules then inserts the coated solar cells as a “foil packet” into a so-called laminator, where they are subsequently immovably joined (“laminated”) to each other under vacuum, heat and pressure in a treatment lasting 15-20 minutes.

This approach has as an objective to encapsulate the thin-film cell so that it becomes impervious to moisture, in particular at the front side, using the following values:

| | Water vapor permeability |
|---|---|
| | in g/m² · d |
| foil, untreated | order of magnitude 10¹ |
| foil, with SiOₓ | 10⁻¹ |
| foil, with SiOₓ and ORCOCER | 10⁻² |
| foil, objective for thin-film cells | 10⁻³ to 10⁻⁴ |

It will be assumed that the conventional and generally advocated approach, namely to make the cover foil exceptionally impervious to moisture, is an obvious solution for the problem which, however, is not at all optimal. Even if the encapsulation is very dense, it is generally impossible—when exposed to wet weather for an extended period of time—to prevent small amounts of moisture from entering the hot-melt layer. Because the front foil formed as a barrier prevents moisture from both entering and escaping, the hot-melt adhesive layer then acts as a storage device for water vapor. In a subsequent heating period, commensurate with the so-called moisture-heat-test according to IEC 61646, the cells are simultaneously subjected to moisture and high temperatures, which is extremely detrimental for the service life and/or the power stability of the thin-film cells.

It is quite difficult and expensive to produce a highly blocking front foil with a density of 10⁻⁴ g/m²·d, because for example three layers ETFE and intermediate barrier layers made of SiOₓ and/or an inorganic-organic hybrid polymer would have to be employed (suppliers of solar foils are presently considering such developments).

In other words: there is a fundamental problem that even if the blocking effect of the front foil is significantly enhanced by the inorganic-organic hybrid polymer, incursion of moisture into the space between solar cell and cover foil cannot be prevented at all or only by employing complex measures (several foils and barrier layers), if the exposure to moisture lasts for a long time. Because the hybrid polymer barrier layer implemented as a cover functions in the same manner in both directions, both incursion and evaporation/diffusion of moisture are similarly prevented. This generates a quasi-storage effect for the moisture, so that the improved encapsulation of the solar cell for reducing the damaging effect from moisture on the cell produces just the opposite effect.

DE 197 32 217 A1 discloses encapsulation for photovoltaic components, wherein according to one embodiment a diffusion barrier layer is directly applied to the solar cell and then coated with an elastic polymer protective layer and a polymer cover foil made, for example, of polycarbonate. The diffusion barrier layer and the elastic polymer protection layer are applied by plasma coating. The polymer foil is also plasma-treated and then laminated together merely by placing the foil on the protective layer. This coating and lamination process therefore requires a high-vacuum system.

The moisture needs to be blocked only by the diffusion barrier layer, which is implemented as an amorphous SiOₓ layer.

An amorphous SiOₓ layer as the sole diffusion barrier for thin-film solar cells cannot guarantee that the solar cells, in particular flexible solar cells, achieve the intended service life. For this reason, DE 197 32 217 A1 appears to propose to cover the polymer cover foil in a final step with a quartz-like hard surface layer which is scratch-resistant and impervious to water vapor.

The lack of a hot-melt adhesive in the method disclosed in DE 197 32 217 A1 should cast some doubt about the durability of the bond between the protective layer and the cover foil when reaching the end of the service life of a thin-film solar cell.

It is an object of the invention to provide a glassless solar power module with at least one flexible thin-film solar cell, wherein the useful service life can be guaranteed even when exposed to moisture, as well as a method for its manufacture which eliminates the aforementioned disadvantages associated with the use of complex special foils.

This object of the invention is attained by the features of claims 1 and 7. Advantageous embodiments are recited in the dependent claims.

Accordingly, the following layer structure, starting from the solar cell, is provided:

At the front side:
an inorganic barrier layer, for example aluminum oxide (Al₂O₃)
an inorganic-organic hybrid polymer barrier layer
a transparent adhesive layer
a transparent cover foil

At the backside:
an adhesive layer
a standard backside foil.

The transparent front cover foil can be made of untreated foils with perviousness to water vapor having a value of about 10 g/m²·d.

The method for producing a solar power module of this type is characterized by the following process steps:
applying an inorganic barrier layer onto the front side of the solar cell (the side facing the light)
applying an inorganic-organic hybrid polymer barrier layer on the front side
applying a transparent adhesive layer on the front side and the backside
applying a transparent cover foil on the front side
applying a cover foil on the backside.

The four last steps can typically be performed in a single operation.

In other words, a highly blocking barrier material, like the aforementioned hybrid polymer, is employed for sealing; however, this material is deposited together with an inorganic barrier layer directly onto the thin-film cells. At the same time, the cover foil is left in its original, relatively transparent state, i.e., no inorganic materials are evaporated on the cover foil. The cover foil is glued together in a typical manner, so that moisture can again escape or “evaporate” in a heat-up phase which follows exposure to moisture. Such “open” system of encapsulating the cells with the barrier layer according to the invention, which directly contacts the cell surface, lowers the stress on the moisture-sensitive solar cell, in particular if cycles of exposure to moisture and heating directly follow one another, as in the simulated moisture-frost test according to IEC 61646 which is relevant for module certification.

Advantageously, a polymer varnish, for example a polycarbonate pre-polymer varnish, can initially be applied for smoothing the surface of a cell and providing a good base for the subsequent layers, because their blocking properties appear to depend strongly on the roughness of the base.

The inorganic-organic hybrid polymer layer can also be applied by immersion, spray-coating or screen printing. It develops its full blocking effect through intimate contact with the previously applied inorganic barrier layer. A sputtered aluminum oxide layer has proven to be optimal for this purpose, because it produces the best surfaces for a strong connection with the following hybrid layer. The blocking effect of this material combination is significantly greater than that of the individual layers, i.e., the inorganic barrier layer and the hybrid polymer. The sequential order of the layer structure—1. inorganic barrier layer, 2. hybrid polymer—, is also important because the high blocking effect cannot be attained when the layers are arranged in reverse order.

Advantageously, a SiOₓ layer can be applied for improving adhesion between the inorganic-organic hybrid polymer and the hot-melt adhesive for the cover foil. This adhesion-promoting layer can be applied, for example, by a plasma process at normal pressure (pa-CVD=plasma-activated Chemical Vapor Deposition), because of his layer need not be very dense.

The invention therefore replaces the conventional “closed” system for encapsulation with an “open” system: a front foil with a small blocking effect is intentionally used, so that moisture that entered the adhesive layer is not prevented from evaporating when the heat-up period begins.

The system of the invention eliminates the need for a front foil with an extremely small permeability for water vapor of 10⁻³ to 10⁻⁴ g/m²·d, which is difficult to attain.

In addition to this technological advantage, a cost advantage arises, because instead of foils made of ETFE/PTFE a less costly foil material can be used, for example foils made of PC (polycarbonate), which are presently not used for covering the front side of solar modules, because they are more permeable for water vapor.

In addition to technological and cost advantages, foils that are not made of fluoropolymers have the distinct advantage that they can be glued to other plastic materials, for example a front-side connector box or a frame providing edge protection, which would be almost impossible PTFE and ETFE.

An additional advantage of the solar power module of the invention relates to its backside: depending on the manufacturing process of the solar cell, a highly effective moisture seal may also be required on the backside, where presently expensive composite foils (for example, plastic-aluminum-plastic, as described above) are employed. The cell can here also be encapsulated with the aforedescribed barrier layer on the backside, so that simpler, less water-vapor-proof and less costly backside foils can be used.

The same foil material used for encapsulating the front side can also be used for the backside. This is also desirable for attaining the same thermal expansion characteristic (avoiding a “bimetal effect”).

Conventional methods, such as reactive sputtering and sputtering from a ceramic target, can be used for applying the inorganic barrier layer (Al₂O₃), for SiO₂ for example also CVD processes, which are well suited for roll-to-roll production of ribbon-type flexible thin-film cells. Similar systems are used in other industries (for example in the glass-forming industry).

The inorganic barrier layer significantly enhances the blocking effect of the inorganic-organic hybrid polymer barrier layer through formation of covalent bonds, while also protecting the surface of the solar cell from possible harmful effects caused by the hybrid polymer barrier layer which is applied in an aqueous alcohol solution.

The invention will now be described with reference to an exemplary embodiment. The drawings show in:

FIG. 1 schematically a conventional layer structure of a solar power module, and

FIG. 2 schematically a layer structure according to the invention.

FIG. 1 has already been described above.

FIG. 2 shows the layer structure according to the invention of a glassless foil module with flexible thin-film cells. The front foil 1b does here no longer include barrier layers 2, 3, but is left in its original state and is relatively permeable. However, the surface of the solar cell 6 is provided directly with the inorganic-organic hybrid polymer barrier layer 3 (ORMOCER). An inorganic barrier layer 2 made of aluminum oxide (Al₂O₃) is disposed underneath the barrier layer 3. However, a polymer varnish layer 5 is initially applied directly on the surface of the solar cell 6 by screen printing, spray-coating or immersion, which is also not routine with conventional encapsulation. The varnish layer 5 itself does not function as a barrier layer, but helps to smooth the roughness of the cell surface. The blocking effect of the subsequent layers depends significantly on the smoothness of the base.

The inorganic-organic hybrid polymer barrier layer 3 can also be applied by immersion, spray-coating or screen printing.

Unlike with “closed” encapsulation, moisture which is absorbed by the hot-melt adhesive 4a, for example EVA, used to glue the polycarbonate front foil 1b and which is regarded as the source for the moisture damaging the cells, is allowed to outdiffuse, because the cover foil 1b is relatively permeable. On the other hand, the intermediate layers 2, 3, 5 prevent moisture from entering the solar cell 6.

An additional transparent SiOₓ layer can be deposited on the inorganic-organic hybrid polymer barrier layer 3 to enhance adhesion between the inorganic-organic hybrid polymer barrier layer 3 and the hot-melt adhesive 4a.

A standard backside foil or the same type of foil used for the front side can also be used for the backside foil 7b. For a moisture-proof encapsulation of the backside, an additional coating 8 made of an inorganic-organic hybrid polymer (ORMOCER), like the front side, can be deposited on the backside of the cells, so that simpler, less water-vapor-proof and less costly backside foils 7b can be used.

### LIST OF REFERENCE SYMBOLS

1a front foil
1b front foil (relatively permeable)
2 inorganic barrier layer made of Al₂O₃
3 inorganic-organic hybrid polymer barrier layer (ORMOCER)
4 hot-melt adhesive
5 varnish layer
6 solar cell
7a composite foil
7b backside foil
8 backside cell coating (ORMOCER)

1. Glassless solar power module comprising at least one flexible thin-film solar cell, and a layer structure, starting from the solar cell (6), as follows:
at the front side:
an inorganic barrier layer (2)
an inorganic-organic hybrid polymer barrier layer (3)
a transparent adhesive layer (4a)
a transparent cover foil (1b).

2. Glassless solar power module according to claim 1, wherein the inorganic barrier layer (2) comprises aluminum oxide (Al₂O₃)

3. Glassless solar power module according to claim 1, wherein a backside of the solar power module comprises an adhesive layer (4b) and a standard backside foil (7b).

4. Glassless solar power module according to claim 1, wherein a polymer varnish layer (5) is applied between the solar cell (6) and the inorganic barrier layer (2).

5. Glassless solar power module according to claim 1, wherein the adhesive layer (4a) is a hot-melt adhesive foil.

6. Glassless solar power module according to claim 1, wherein the cover foil (1b) is made of polycarbonate.

7. Method for producing a glassless solar power module with at least one flexible thin-film solar cell, comprising the following process steps:
applying an inorganic barrier layer on the front side of the solar cell
applying an inorganic-organic hybrid polymer barrier layer on the front side
applying a transparent adhesive layer on the front
applying a transparent cover foil on the front side.

8. Method according to claim 7, wherein aluminum oxide is applied as the organic barrier layer by reactive sputtering.

9. Method according to claim 7, wherein the inorganic-organic hybrid polymer barrier layer is applied by immersion, spray-coating or screen printing.

10. Method according to one of the claim 7, wherein a polymer varnish is applied directly on the surface of the solar cell between the solar cell and the inorganic barrier layer.

11. Method according to claim 10, wherein the varnish is applied by immersion, spray-coating or screen printing.

12. Method according to claim 7, further comprising the step of applying an adhesive layer on the backside of the solar module.

13. Method according to claim 12, further comprising the step of applying a cover foil on the adhesive layer.
